(19) United States
(12) Patent Application Publication
(10) Pub. No.: US 2003/0107132 A1
(43) Pub. Date: Jun. 12, 2003

(54) Structure of the metal bumping on the input/output connector of a substrate or wafer and method for manufacturing the same

(75) Inventors: Pang-Ming Chiang, Hsin-Chu Hsien (TW); Shyuan-Fang Chen, Taipei (TW); Jyh-Rong Lin, Tu-Cheng City (TW); Shu-Chin Chou, Hsin-Chu Hsien (TW)

Correspondence Address: DOUGHERTY & TROXELL, ONE SKYLINE PLACE, SUITE 1404, 5205 LEESBURG PIKE, FALLS CHURCH, VA, 22041, US

(73) Assignees: INDUSTRIAL TECHNOLOGY RESEARCH INSTITUTE; WHA YU INDUSTRIAL CO., LTD.

(21) Appl. No.: 09/984,695

(22) Filed: Oct. 31, 2001

(51) Int. Cl. H01L 23/48

(52) U.S. Cl. 257/741

(57) ABSTRACT

A metal bumping structure on the input/output connector of a substrate or wafer, which is a metal conductor composed of multiple metal layers overlap the connector pad, characterized in that the overlapped outer or upper metal layer is thinner than the inner or lower metal layer, and the outer or upper metal layer that form the pillar style whose conductivity, connectivity and corrosion resist are better than the inner or lower metal layer, such that the bumping connector has better conductivity, connectivity and not easy to be corroded. It combines the photoresist, exposure, development with the electroless plating method to form the patterns and shapes of the expected object; wherein, the photoresist is to limit the deposition direction of the electroless, plating. If no limit on the electroless plating, it will cause isotropic deposition, as to simultaneously strive upward and around increasing; thus the photoresist is to assist with the electroless plating to form expected patterns and shapes.

### BACKGROUND OF THE INVENTION

1. Field of the Invention

The present invention relates to a metal bumping structure on the input/output connector of a substrate or wafer, especially to a structure having multiple metal layers in which the overlapped outer or upper layer metal is thinner than the inner or lower metal layer, and the outer or upper metal layer that form the pillar style whose conductivity, connectivity and corrosion resist are better than the inner or lower metal layer, such that the bumping connector has better conductivity, connectivity and not easy to be corroded.

2. Description of the Prior Art

As shown in FIG. 1, the conventional electroplating gold bumping method contains the processes of (1) Sputtering TiW and Au, (2) Coating photoresist, (3) Exposure, (4) Development, (5) Electroplating, (6) Photoresist removing (7) Etching sputtered layer. But there exist defects of high cost in equipment and mass production is not achievable.

To improve the defect, a method of “Electroless plating Ni/Gold bumping” is developed. The so called “Electroless plating” is a method to reduce and separate out the metal ion which form the metal film on the object from the solvent, and it includes the following two processings:

1. Chemical reduction: It reduces and separates the metal ion out onto the plated object by reducing agent or separating out after replacing.

2. Replacement: Its condition is that the plated object is easier to lose electrons than the metal solvent. As the plated object lose the electrons and dissolve in the solvent, then the metal ion capture the electrons in the solvent and separate out of the plated object surface.

Said “Electroless plating Ni Gold bumping” includes the processes shown in FIG. 2 as foloows: (1) Zincasting, (2) Electroless plating of Ni, (3) Electroless plating of Au (replacement plating of gold) etc. It can attain the advantages of equipment cost low, and mass production, but there exists the defect that could not make the minimum line width.

Owing to there existing defects of above descriptions on the conventional “Gold bumping” or “Electroless plating Ni/Gold bumping”, the inventor then develop this present invention to improve on the defects mentioned above a long time of searching.

### SUMMARY OF THE INVENTION

Accordingly, the invention provides a metal bumping structure on the input/output connector of a substrate or wafer. It is an object of the present invention to disclose the metal bumping structure on the input/output connector of a substrate or wafer, and, by using the mask process and electroless plating process, it can attain the advantages of equipment cost low, mass production and minimum line width performance.

A more complete understanding of these and other features and advantages of the present invention will become apparent from a careful consideration of the following detailed description of certain embodiments illustrated in the accompanying drawings.

### DETAILED DESCRIPTION OF THE PREFERRED EMBODIMENTS

As shown in FIGS. 3˜12, the metal bumping structure on the input/output connector of a substrate or wafer of present invention is a metal conductor composed of multiple metal layers overlapped to a connector pad, and the materials of the multiple metal layers are made of metal, alloy or compound. The overlapped outer or upper metal layer is thinner than the inner or lower metal layer, and the outer or upper metal layer that form the pillar style whose conductivity, connectivity and corrosion resist are better than the inner or lower metal layer, such that the bumping connector has better conductivity, connectivity and not easy to be corroded. Wherein the inner or lower metal layer is Ni, its alloy or its compound, and the outer or upper metal layer is Au, its alloy or its compound. The outer metal layer structure extends to the rim of pillar and fully covers the inner or lower metal layer such that the corrosion of inner or lower metal layer is prevented, and the bumping edge does not exceed the pad area or the bumping edge exceeds the pad area but does not exceed the one-second of the pitch between two pads.

The conductor is preferrably composed of Al, Cu, Ag or Au, or their alloys, so as to construct and make use of the same or different kind metal, such that make well connectivity The method of manufacturing metal bumping structure on the input/output connector of a substrate or wafer comprising the steps of electroless plating photoresist, exposure, development and photoresist removing to construct the metal conductor of the multiple metal layers upon the input/output connector pad. Otherwise, the method is made use of electroless plating, in which the metal ion is replaced in the silvent or, performing chemical reduction method in the solvent contains reducing agent, single or repeat mixing both of the former processes to attain, and adjust it depend on the elements or the concentration of the solvent to deposit a metal, its alloy or its compound, such that to construct the overlap of the multiple metal layers, and the outer or upper metal layer is thinner than the inner or lower metal layer, then the flatness of the top bumping connector without extension of the metal bumping is formed.

### EXAMPLE A1

Basically, as shown in FIG. 3, the first example of a metal bumping structure on the input/output connector of a substrate or wafer is: the upper layer or outer layer (A) forming of a metal, its alloy or its compound, the thickness of both the upper layer and outer layer are approximately the same, the lower layer or the inner layer (B) is formed of a different kind of metal, its alloy or its compound to (A). The deposition to the lower layer, its alloy or its compound is repressed by the photoresist. When the original metal of the pad is Al, then (A) is Au, its alloy or its compound, (B) is Ni, its alloy or its compound.

### EXAMPLE A2

As shown in FIG. 4, the second example of a metal bumping structure on the input/output connector of a substrate or wafer is: The upper layer or outer layer (A) is formed of a metal, its alloy or its compound, the upper layer and the outer layer are different in thickness, the lower layer and the inner layer (B) is formed of a different kind of metal, its alloy or its compound to (A). The deposition to the lower layer, its alloy or its compound is repressed by the photoresist. When the original metal of the pad is Al, then (A) is Au, its alloy or its compound, (B) is Ni, its alloy or its compound.

### EXAMPLE A3

As shown in FIG. 5, the third example of a metal bumping structure on the input/output connector of a substrate or wafer is: the upper layer or outer layer (A) is formed of a metal, its alloy or its compound, the lower layer (B) is formed of a different kind of metal, to alloy or its compound to (A). The deposition to both of the upper layer and lower layer are repressed by the photoresist. When the original metal of the pad is Al, then (A) is Au, its alloy or its compound, (B) is Ni, its alloy or its compound.

### EXAMPLE A4

As shown in FIG. 6, the forth example of a metal bumping structure on the input/output connector of a substrate or wafer is: the upper layer or outer layer (A) is formed of a metal, its alloy or its compound, the lower layer or the inner layer (B) is formed of a different kind of metal, its alloy or its compound to (A). The deposition to the lower layer, alloy or compound is not repressed by the photoresist. When the original metal of the pad is Al, then (A) is Au, its alloy or its compound, (B) is Ni, its alloy or its compound.

### EXAMPLE A5

As shown in FIG. 7, the fifth example of a metal bumping structure on the input/output connector of a substrate or wafer is: the upper layer (A) is fromed of a metal, its alloy or its compound, the lower layer (B) is formed of a different kind metal, its alloy or its compound to (A). The deposition to the lower layer is not repressed by the photoresist. When the original metal of the pad is Al, then (A) is Au, its alloy or its compound, (B) is Ni, its alloy or its compound.

### EXAMPLE A6

As shown in FIG. 8, the sixth example of a metal bumping structure on the input/output connector of a substrate or wafer is: the upper layer or outer layer (A) is formed of a metal, its alloy or its compound, the lower layer or the inner layer (B) is formed of a different kind metal, its alloy or its compound (A). The deposition to the lower layer is not repressed by the photoresist. When the original metal of the pad is Al, then (A) is Au, its alloy or its compound, (B) is Ni, its alloy or its compound.

### EXAMPLE A7

As shown in FIG. 9, the seventh example of a metal bumping structure on the input/output connector of a substrate or wafer is: the upper layer or outer layer (A) is formed of a metal, its alloy or its compound, both the thickness of the upper layer and outer layer are approximately the same, the middle layer (B) is formed of a different kind of metal, its alloy or its compound to the (A). The deposition to the middle layer is repressed by the photoresist. The lower layer or the inner layer (C) is formed of another different kind of metal, its alloy or its compound to the (A) and (B). When the original metal of the pad is Cu, then (A) is Au, its alloy or its compound, (B) is Ni, its alloy or its compound, and (C) is Pd, its alloy or its compound.

### EXAMPLE A8

As shown in FIG. 10, the eighth example of a metal bumping structure on the input/output connector of a substrate or wafer is: the upper layer or outer layer (A) is formed of a metal, its alloy or its compound, rach of the thickness of the upper layer or the outer layer is the different, the middle layer (B) is formed of a different metal, its alloy or its compound to the (A). The deposition to the middle layer is repressed by the photoresist. The lower layer or the inner layer (C) is made of another different kind of metal, alloy or compound to the (A) and (B). When the original metal of the pad is Cu, then (A) is Au, its alloy or its compound, (B) is Ni, its alloy or its compound, and (C) is Pd, its alloy or its compound.

### EXAMPLE A9

As shown in FIG. 11, the ninth example of a metal bumping structure on the input/output connector of a substrate or wafer is: the upper layer (A) is formed of a kind metal, its alloy or its compound, the middle layer (B) is formed of a different kind metal, its alloy or its compound to (A). The depositions to the upper layer and middle layer are repressed by the photoresist. The lower layer (C) is made of another different kind of metal, its alloy or its compound to the (A) and (B). When the original metal of the pad is Cu, then (A) is Au, its alloy or its compound, (B) is Ni, its alloy or its compound, and (C) is Pd, its alloy or its compound.

### EXAMPLE A10

As shown in FIG. 12, the tenth example of a metal bumping structure on the input/output connector of a substrate or wafer is: the upper layer (A) is formed of a kind of metal, its alloy or its compound, the middle layer (B) is formed of a different kind of metal, its alloy or its compound to (A). The deposition to the middle layer is not repressed by the photoresist. The lower layer or the inner layer (C) is formed of a different kind metal, its alloy or its compound to (A) and (B). When the original metal of the pad is Cu, then (A) is Au, its alloy or its compound, (B) is Ni, its alloy or its compound, and (C) is Pd, its alloy or its compound.

### EXAMPLE A11

As shown in FIG. 13, the eleventh example of a metal bumping structure on the input/output connector of a substrate or wafer is: the upper layer (A) is formed of a metal, its alloy or its compound, the middle layer (B) is formed of a different metal, its alloy or its compound to (A). The deposition to the middle layer is not repressed by the photoresist. The lower layer (C) is formed of another different kind of metal, its alloy or its compound to (A) and (B). When the original of the pad metal is Cu, then (A) is Au, its alloy or its compound, (B) is Ni, its alloy or its compound, and (C) is Pd, its alloy or its compound.

### EXAMPLE A12

As shown in FIG. 14, the twelfth example of a metal bumping structure on the input/output connector of a substrate or wafer is: the upper layer or the outer layer (A) is made of a metal, its alloy or its compound, the middle layer (B) is formed of a different metal, its alloy or its compound to (A). The deposition to the middle layer is not repressed by the photoresist. The lower layer and the inner layer (C) is formed of another different kind metal, alloy or compound to (A) and (B). When the original metal of the pad is Cu, then (A) is Au, its alloy or its compound, (B) is Ni, its alloy or its compound, and (C) is Pd, its alloy or its compound.

### EXAMPLE B1

Basically, as shown in FIG. 15, the first example of method for manufacturing metal bumping on the input/output connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating a metal layer by electroless plating method;

(6) Photoresist removing;

(7) By electroless plating method, plating an another metal onto the surface of the metal layer to construct the bumping

Wherein the main objects of step (7) are:

1. To prevent the metal formed in the step (5) to be corroded.

2. Bonding on the top of the bumping.

3. To enhance the conductivity and decrease the resistance.

### EXAMPLE B1-1

When the original metal of the pad is Al, the manufacturing steps can be changed as follows:

(4) The Al on the pad is replaced by Zn, its alloy or its compound;

(5) In the step (4), the surface of Zn is replaced by Ni, its alloy or its compound;

(7) In the step (5), the upper edge and the rim surface of the Ni is replaced or deposited by Au, its alloy or its compound;

so as to construct the bumping.

### EXAMPLE B2

Basically, as shown in FIG. 16, the second kind of method for manufacturing metal bumping on the input/output connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating one metal layer by electroless plating method;

(6) By electroless plating method, plating an another metal on the surface of the metal layer formed by step (5) to construct the bumping;

(7) Photoresist removing;

(8) By electroless plating method, again plating the same metal in the step (6) on the rim of the metal formed by step (5).

so as to construct the bumping.

### EXAMPLE B2-1

When the original metal on the pad is Al, the manufacturing steps can be changed as follows:

(4) The Al on the pad is replaced by Zn, alloy or compound;

(5) In the step (4), the surface of Zn is replaced by Ni, its alloy or its compound;

(6) In the step (5), the upper edge surface of Ni is replaced or deposited by Au, its alloy or its compound;

(8) In the step (5), the rim surface of Ni is replaced or deposited by Au, its alloy or its compound;

so as to construct the bumping.

### EXAMPLE B3

Basically, as shown in FIG. 17, the third kind of method for manufacturing method bumping on the input/output connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating one metal layer by electroless plating method;

(6) By electroless plating method, plating an another metal on the surface of the metal layer formed by step (5);

(7) Photoresist removing;

so as to construct the bumping.

### EXAMPLE B3-1

When the original metal of the pad is Al, the manufacturing steps can be changed as follows:

(4) The Al on the pad is replaced by Zn, its alloy or its compound;

(5) In the process number four, the surface of the Zn is replaced by Ni, alloy or compound;

(6) In the step (5), the upper edge and the rim surface of Ni is replaced or deposited by Au, its alloy or its compound;

so as to construct the bumping.

### EXAMPLE 4

Basically, as shown in FIG. 18, the forth kind of method for manufacturing metal bumping on the input/output connector pad of a substrate or wafer comprises the steps of:

(1) Pre-treatment of the electroless plating;

(2) Plating one metal layer by electroless plating method;

(3) By electroless plating method, plating an another metal on the surface of the metal layer formed by process number two;

(4) Coating photoresist;

(5) Adding mask to exposure;

(6) Developing to expose the top metal of the pad;

(7) By electroless plating method, plating the same thicker metal on the top surface of the metal layer formed by step (2);

(8) Photoresist removing;

So as to construct the bumping.

### EXAMPLE B4-1

When the original metal, on the pad is Al, the manufacturing steps can be changed as follows:

(1) The Al on the pad is replaced by Zn, its alloy or its compound;

(2) In the step (1), the surface of Zn is replaced by Ni, its alloy or its compound;

(3) In the step (2), the surface of Ni is replaced or deposited by Au, its alloy or its compound;

(7) In the step (3), the top surface of the Au is deposited thicker by Au, its alloy or its compound;

so as too construct the bumping.

### EXAMPLE B5

Basically, as shown in FIG. 19, the fifth example of method for manufacturing metal bumping on the input/output connector pad of a substrate or wafer comprises the steps of:

(1) Pre-process of the electroless plating;

(2) By electroless plating method, plating one metal layer;

(3) Coating photoresist;

(4) Adding mask to exposure;

(5) Developing to expose the top metal of the pad;

(6) By electroless plating method, plating an another metal on the surface of the metal layer formed by step (2);

(7) Photoresist removing;

so as to construct the bumping.

### EXAMPLE 5-1

When the original metal of the pad is Al, the manufacturing steps can be changed as follows:

(1) The Al on the pad is replaced by Zn, its alloy or its compound;

(2) In the step (1), the surface of Zn is replaced by Ni, its alloy or its compound;

(3) In the step (2), the surface of Ni is replaced or deposited by Au, its alloy or its compound;

so as to construct the bumping.

### EXAMPLE B-6

Basically, as shown in FIG. 20, the sixth example of method for manufacturing metal bumping on the input/output connector pad of a substrate or wafer comprises the steps of:

(1) Pre-treatment of the electroless plating;

(2) Plating one metal layer by electroless plating method;

(3) Coating photoresist;

(4) Adding mask to exposure;

(5) Developing to expose the top metal of the pad;

(6) By electroless plating method, plating an another metal on the surface of the metal layer formed by step (2);

(7) Photoresist removing;

(8) By electroless plating method, plating a thicker layer of metal same as that used in step (6) on the rim of the metal formed by step (2) and on the top surface of the metal layer formed by step (6);

so as to construct the bumping.

### EXAMPLE 6-1

When the original metal of the pad is Al, the manufacturing steps can be changed as follows:

(1) The Al on the pad surface is replaced by Zn, its alloy or its compound;

(2) In the step (1), the surface of Zn is replaced by Ni, its alloy or its compound;

(3) In the step (2), the surface of Ni is replaced or deposited by Au, its alloy or its compound;

(8) The rim in step (2) and the top surface in step (6) are changed by plating thicker layers of metal same as that in the step (6);

so as to construct the bumping.

### EXAMPLE B7

Basically, as shown in FIG. 21, the seventh example of method for manufacturing metal bumping on the input/output connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating one metal layer By electroless plating method;

(6) Photoresist removing;

(7) By electroless plating method, plating an another metal on the surface of the metal layer formed by step (5);

so as to construct the bumping.

Wherein the main purposes of manufacturing step (7) are:

1. To prevent the metal formed in the step (5) to be corroded.

2. Bonding on the top of the bumping.

3. To enhance the conductivity and decrease the resistance.

### EXAMPLE B7-1

When the original metal on the pad is Cu, the manufacture processes:

(4) The Cu on the pad is replaced by Pd, its alloy or its compound;

(5) In the step (4), the surface of Pd is replaced by Ni, its alloy or its compound;

(7) In the step (5), the upper edge and the rim surface of Ni is replaced or deposited by Au, its alloy or its compound;

so as to construct the bumping.

### EXAMPLE B8

Basically, as shown in FIG. 22, the eighth example of method for manufacturing metal bumping on the input/output connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating one metal layer by electroless plating method;

(6) By electroless plating method, plating an another metal on the surface of the metal layer formed by step (5) to construct the bumping;

(7) Photoresist removing;

(8) By electroless plating method, again plating the metal same as that in the step (6) on the rim of the metal formed by step (5).

so as to construct the bumping.

### EXAMPLE B8-1

When the original metal of the pad is Cu, the manufacturing steps can be changed as follows:

(4) The Cu on the pad is replaced by Pd, its alloy or its compound;

(5) In the step (4), the surface of Pd is replaced by Ni, its alloy or its compound;

(6) In the step (5), the upper edge surface of Ni is replaced or deposited by Au, its alloy or its compound;

(8) In the step (5), the rim surface of Ni is replaced or deposited by Au, its alloy or its compound;

so as to construct the bumping.

### EXAMPLE B9

Basically, as as shown in FIG. 23, the ninth example of method for manufacturing metal bumping on the input/out connector pad of a substrate or wafer comprises the steps of:

(1) Coating photoresist;

(2) Adding mask to exposure;

(3) Developing to expose the metal of the pad;

(4) Pre-treatment of the electroless plating;

(5) Plating, one metal layer by electroless plating method;

(6) By electroless plating method, plating an another metal on the surface of the metal layer formed by step (5);

(7) Photoresist removing;

so as to construct the bumping.

### EXAMPLE B9-1

When the original metal of the pad is Cu, the manufacturing steps can be changed as follows:

(4) The Cu on the pad surface is replaced by Pd, its alloy or its compound;

(5) In the step (4), the surface of Pd is replaced by Ni, its alloy or its compound;

(6) In the step (5), the upper edge and the rim surface of Ni is replaced or deposited by Au, its alloy or its compound;

so as to construct the bumping.

### EXAMPLE 10

Basically, as shown in FIG. 24, the tenth example of method for manufacturing metal bumping on the input/output connector pad of a substrate or wafer comprises the steps of:

(1) Pre-treatment of the electroless plating;

(2) Plating one metal layer by electroless plating method;

(3) By electroless plating method, plating an another metal on the surface of the metal layer formed by step (2);

(4) Coating photoresist;

(5) Adding mask to exposure;

(6) Developing to expose the top metal of the pad;

(7) By electroless plating method, plating the same thicker metal on the top surface of the metal layer formed by step (2);

(8) Photoresist removing;

so as to construct the bumping.

### EXAMPLE 10-1

When the original metal of the pad is Cu, the manufacturing steps can be changed as follows:

(1) The Cu on the pad surface is replaced by Pd, its alloy or its compound;

(2) In the step (1), the surface of Pd is replaced by Ni, its alloy or its compound;

(3) In the step (2), the surface of Ni is replaced or deposited by Au, its alloy or its compound;

(7) In the step (3), the top surface of Au is deposited thicker by Au, its alloy or its compound;

so as to construct the bumping.

### EXAMPLE B11

Basically, as shown in FIG. 25, the eleventh example of method for manufacturing metal bumping on the input/output connector pad of a substrate or wafer by:

(1) Pre-treatment of the electroless plating;

(2) Plating one metal layer by electroless plating method;

(3) Coating photoresist;

(4) Adding mask to exposure;

(5) Developing to expose the top metal of the pad;

(6) By electroless plating method, plating an another metal on the surface of the metal layer formed by step (2);

(7) Photoresist removing;

so as to construct the bumping.

### EXAMPLE B11-1

When the original metal of the pad is Cu, the manufacturing steps can be changed follows:

(1) The Cu of the pad surface is replaced by Pd, its alloy or its compound;

(2) In the step (1), the surface of the Pd is replaced by Ni, its alloy or its compound;

(3) In the step (2), the surface of the Ni is replaced or deposited by Au, its alloy or its compound;

so as to construct the bumping.

### EXAMPLE B12

Basically, as shown in FIG. 26 illustration, the twelfth example of method for manufacturing metal bumping the input/output connector pad of a substrate or wafer comprises the steps of:

(1) Pre-treatment of the electroless plating;

(2) Plating one metal layer by electroless plating method;

(3) Coating photoresist;

(4) Adding mask to exposure;

(5) Developing to expose the top metal of the pad;

(6) By electroless plating method, plating an another metal on the surface of the metal layer formed by step (2);

(7) Photoresist removing;

(8) By electroless plating method, plating a thicker layer of metal same as that used in step (6) on the rim of the metal formed by step (2) and on the top surface of the metal layer formed by step (6);

so as to construct the bumping.

### EXAMPLE B12-1

When the original metal of the pad is Cu, the manufacturing steps can be changed as follows:

(1) The Cu of the pad surface is replaced by Pd, its alloy or its compound;

(2) In the step (1), the surface of the Pd is replaced by Ni, its alloy or its compound;

(3) In the step (2), the surface of Ni is replaced or deposited by Au, its alloy or its compound;

(8) The rim in the step (2) and the top surface in the step (6) are plating thicker layers of metal same as that used in step (6);

so as to construct the bumping.

As explained above, in the present invention to a metal bumping, structure on the input/output connector of a substrate or wafer, the multiple metal layers which overlap to outer or upper metal layer metal is thinner than the inner or lower metal layer, and the outer or upper metal layer that form the pillar style whose conductivity, connectivity and corrosion resist are better than the inner or lower metal layer, such that the bumping connector has better conductivity, connectivity and not easy to be corroded. The invention is not yet implemented publicly, so it does not violate the patent law, its my honor to accept your adoption.

### BRIEF DESCRIPTION OF THE DRAWINGS

FIG. 1 illustrates a conventional gold bumping flow diagram.

FIG. 2 illustrates a conventional second kind of gold bumping flow diagram.

FIG. 3 illustrates the first example of the metal bumping frame of the present invention.

FIG. 4 illustrates the second example of the metal bumping frame of the present invention.

FIG. 5 illustrates the third example of the metal bumping frame of the present invention.

FIG. 6 illustrates the fourth example of the metal bumping frame of the present invention.

FIG. 7 illustrates the fifth example of the metal bumping frame of the present invention.

FIG. 8 illustrates the sixth example of the metal bumping frame of the present invention.

FIG. 9 illustrates seventh example of the metal bumping frame of the present invention.

FIG. 10 illustrates the eighth example of the metal bumping frame of the present invention.

FIG. 11 illustrates the ninth example of the metal bumping frame of the present invention.

FIG. 12 illustrates tenth example of the metal bumping frame of the present invention.

FIG. 13 illustrates the eleventh example of the metal bumping frame of the present invention.

FIG. 14 illustrates the twelfth example of the metal bumping frame of the present invention.

FIG. 15 illustrates the first example of the manufacture flow diagram of the present invention.

FIG. 16 illustrates the second example of the manufacture flow diagram of the present invention.

FIG. 17 illustrates the third example of the manufacture flow diagram of the present invention.

FIG. 18 illustrates the fourth example of the manufacture flow diagram of the present invention.

FIG. 19 illustrates the fifth example of the manufacture flow diagram of the present invention.

FIG. 20 illustrates the sixth example of the manufacture flow diagram of the present invention.

FIG. 21 illustrates the seventh example of the manufacture flow diagram of the present invention.

FIG. 22 illustrates the eighth example of the manufacture flow diagram of the present invention.

FIG. 23 illustrates the ninth example of the manufacture flow diagram of the present invention.

FIG. 24 illustrates the tenth example of the manufacture flow diagram of the present invention.

FIG. 25 illustrates the eleventh example of the manufacture flow diagram of the present invention.

FIG. 26 illustrates the twelfth example of the manufacture flow diagram of the present invention.

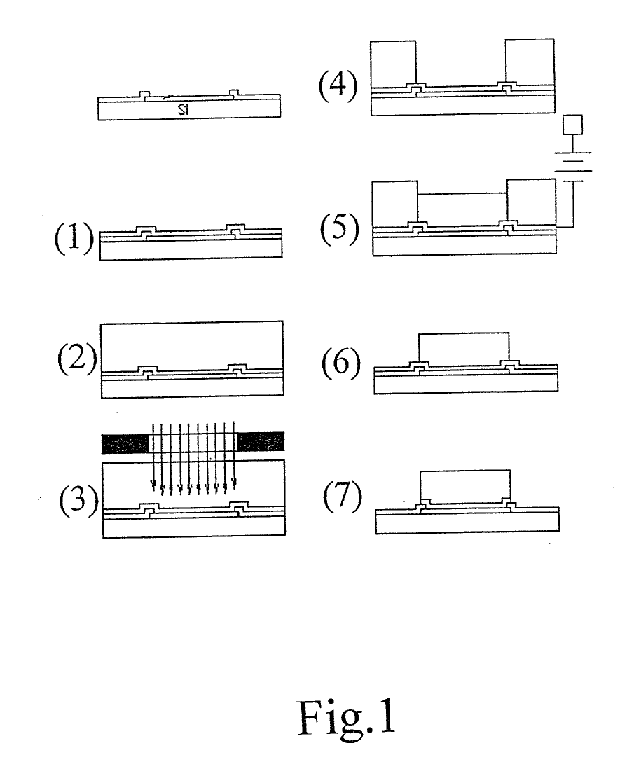

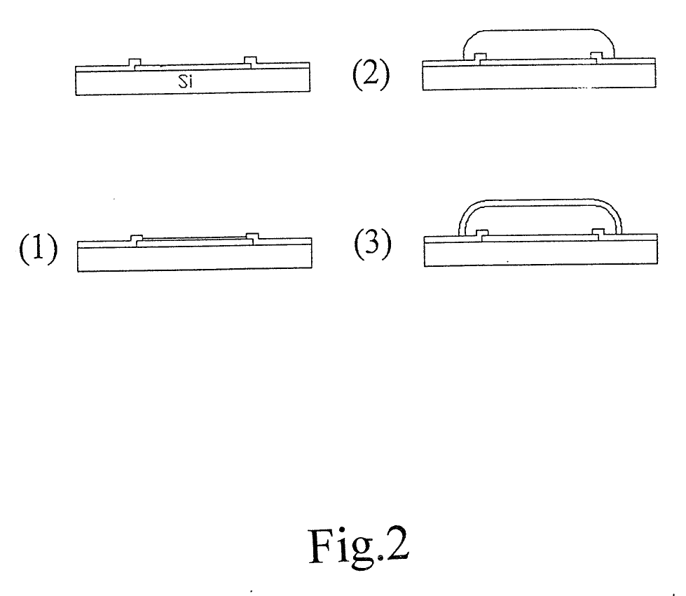

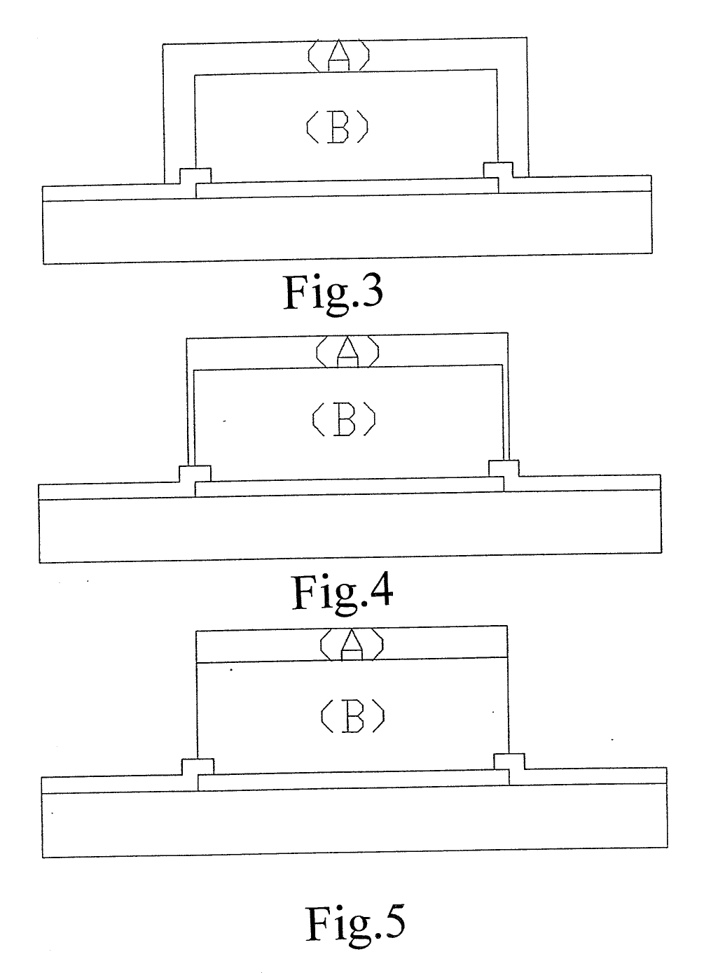

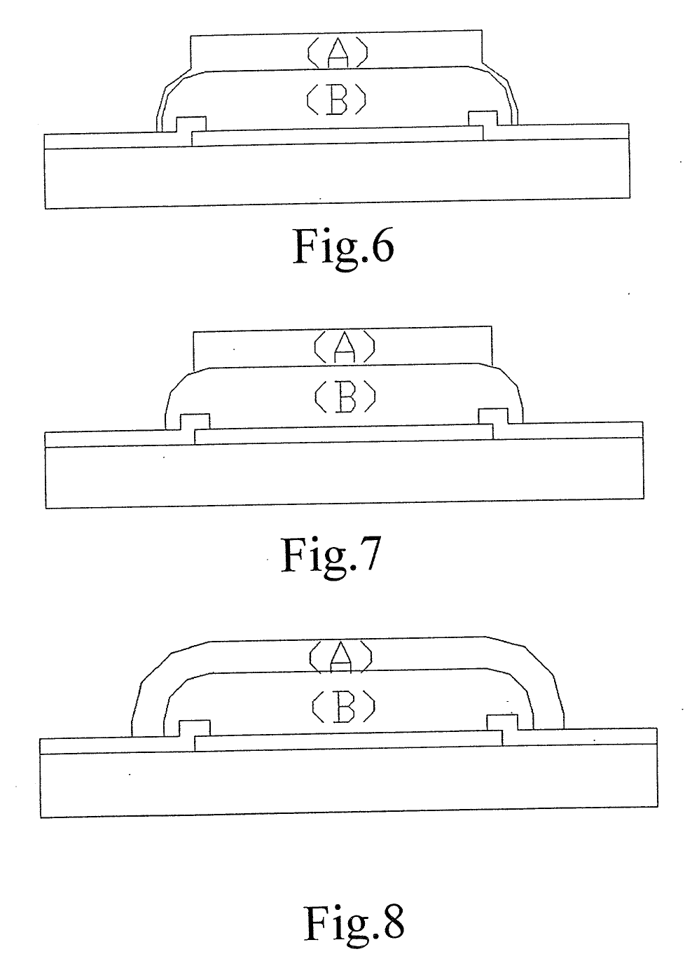

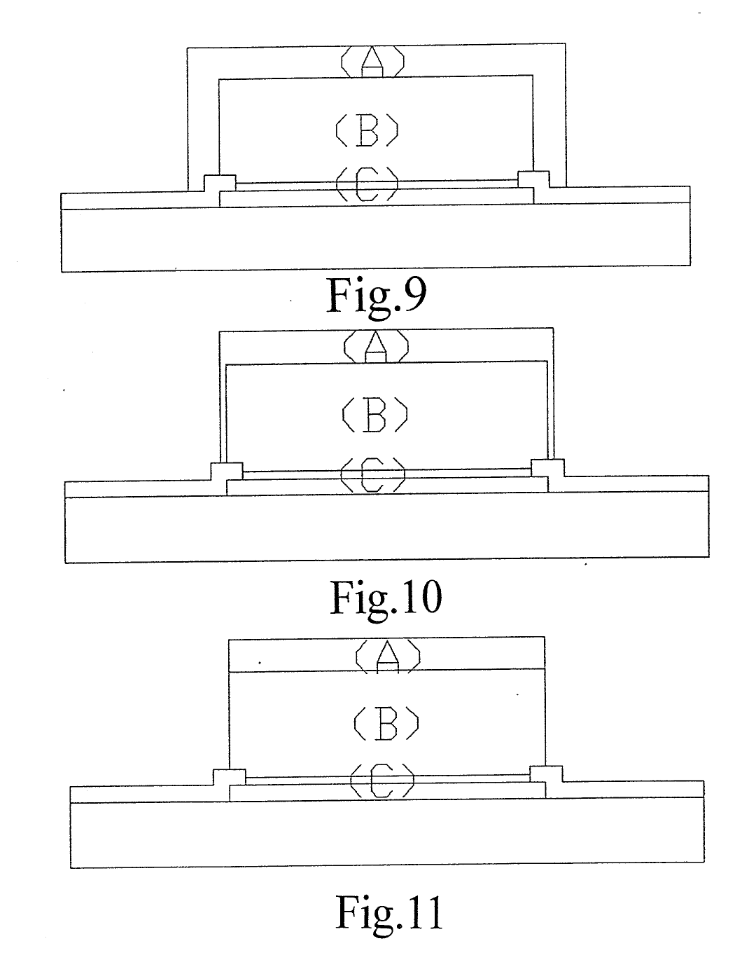

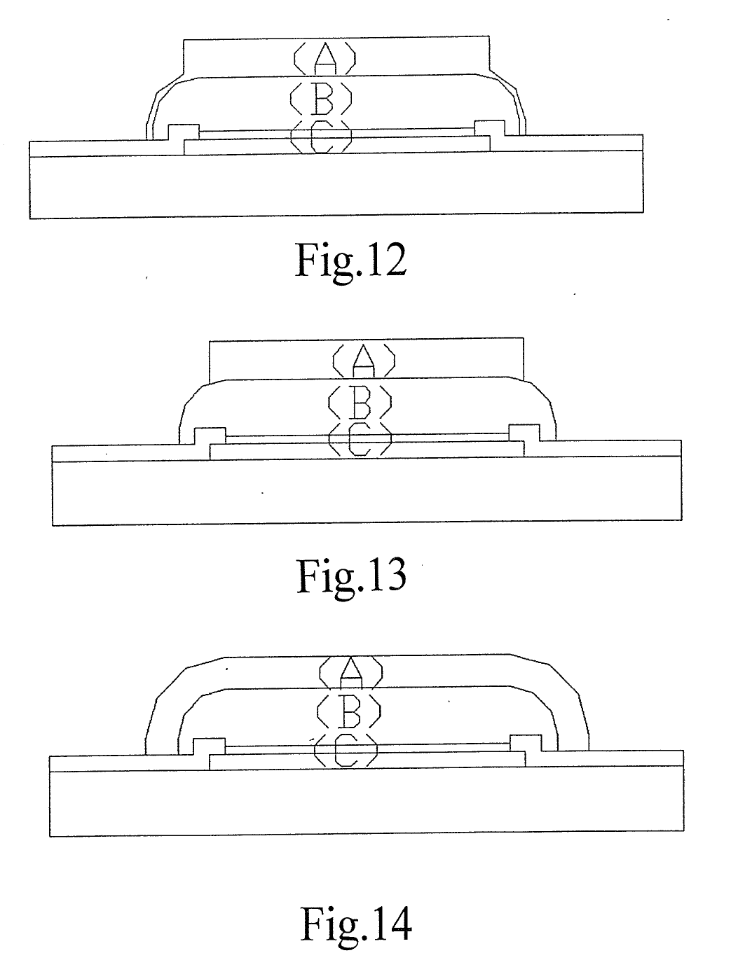

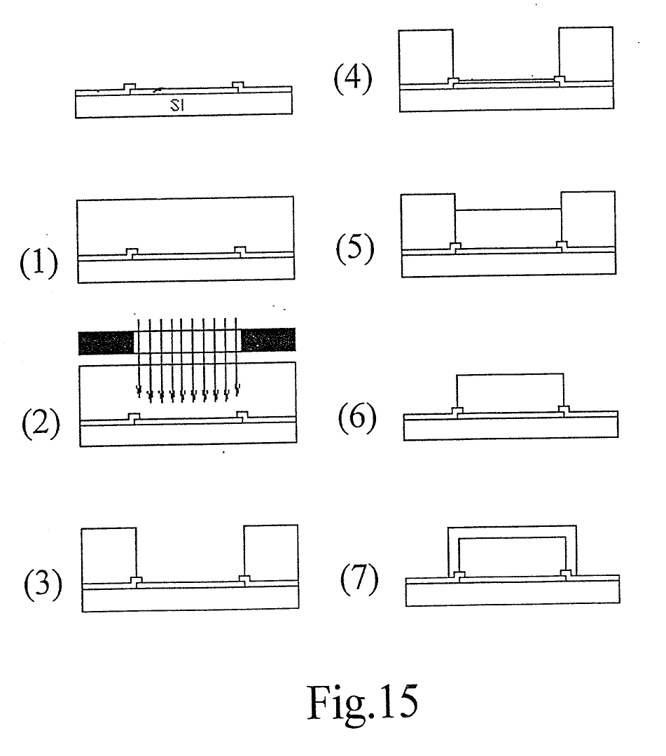

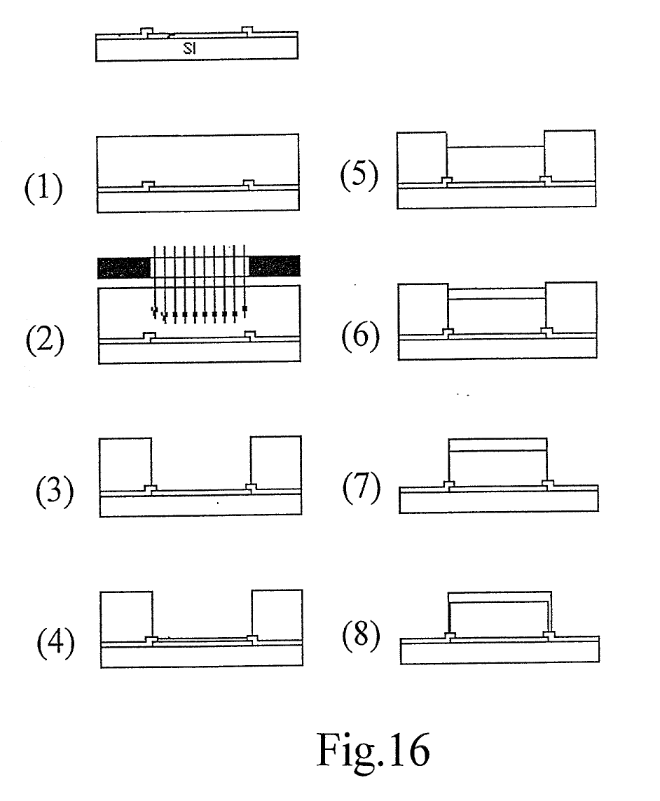

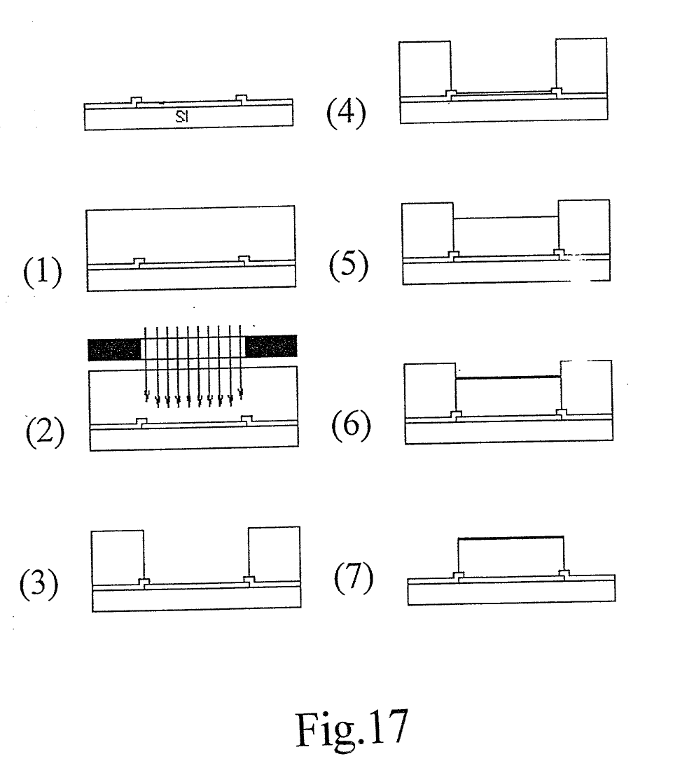

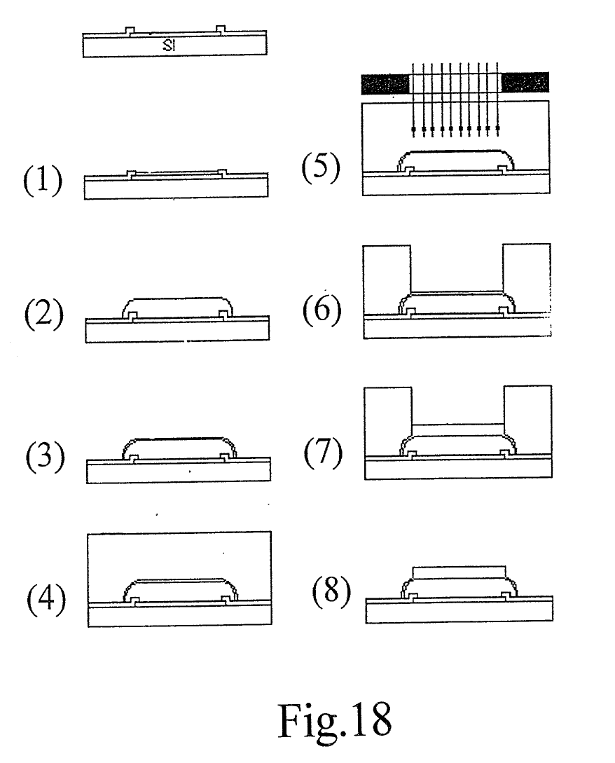

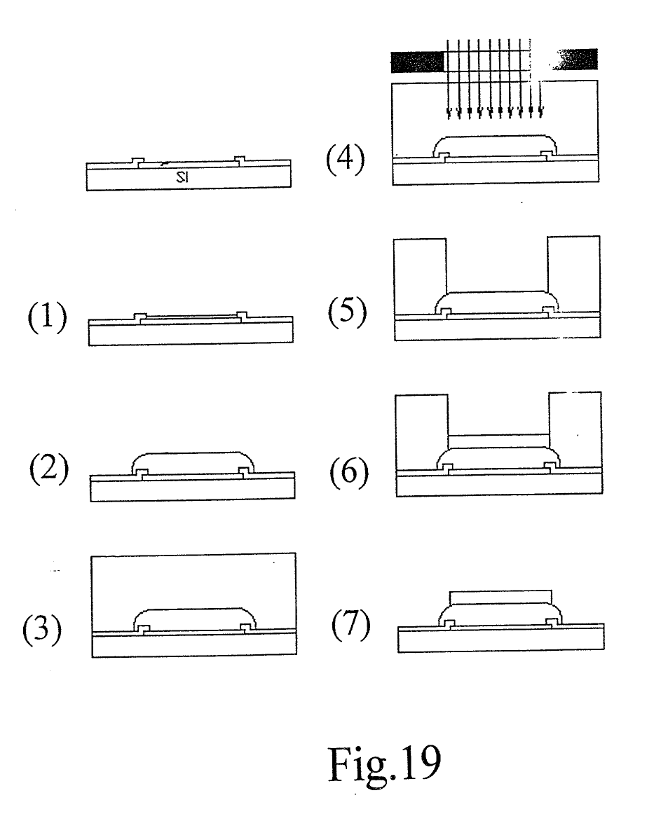

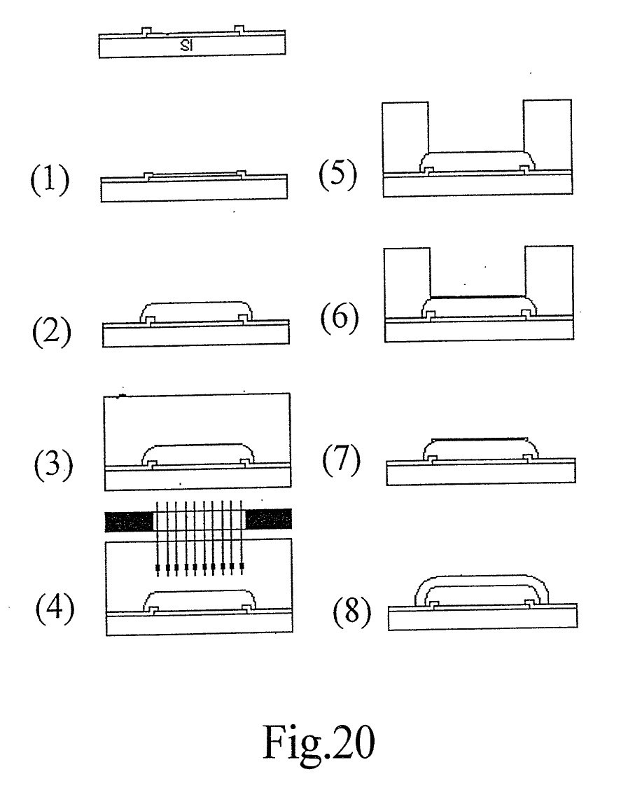

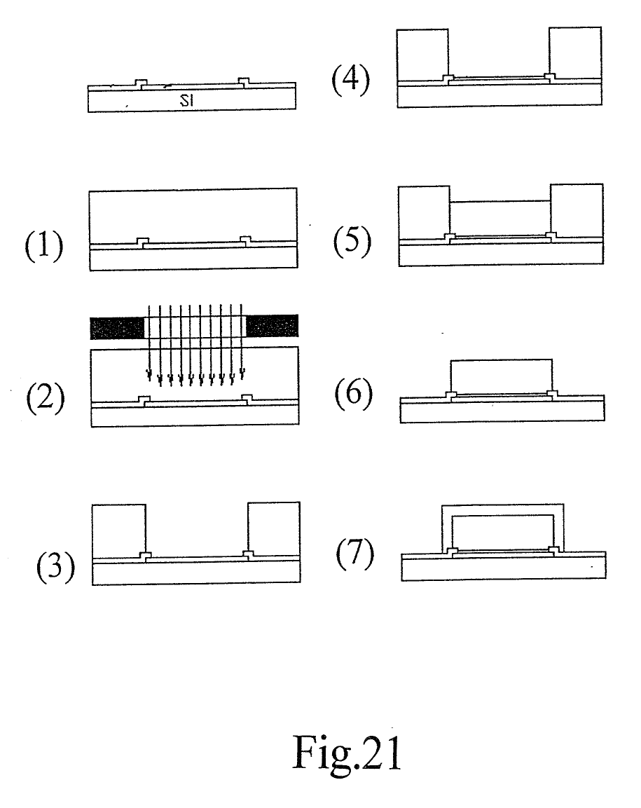

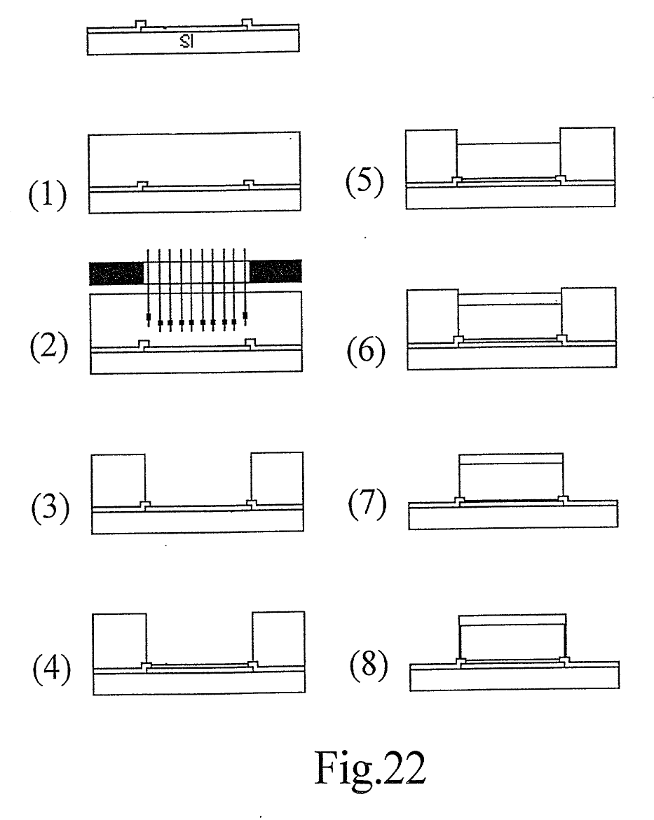

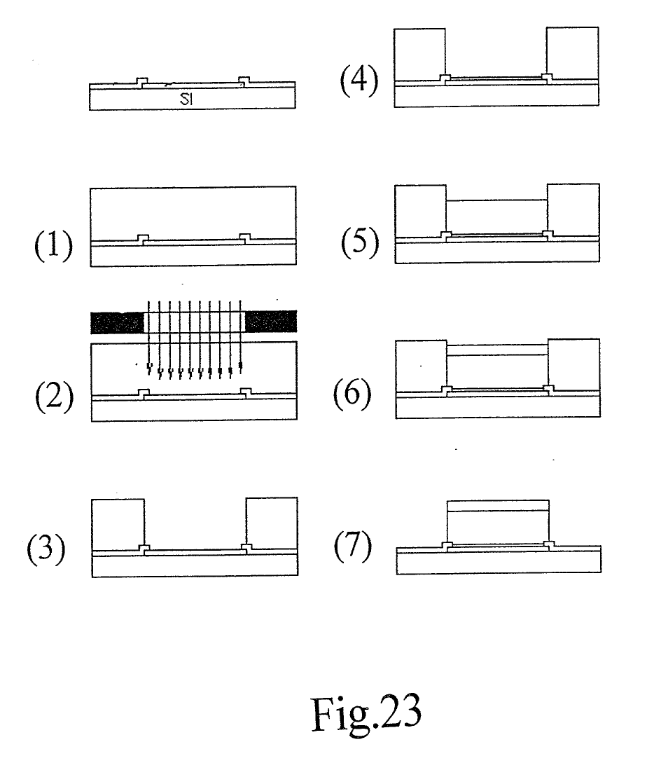

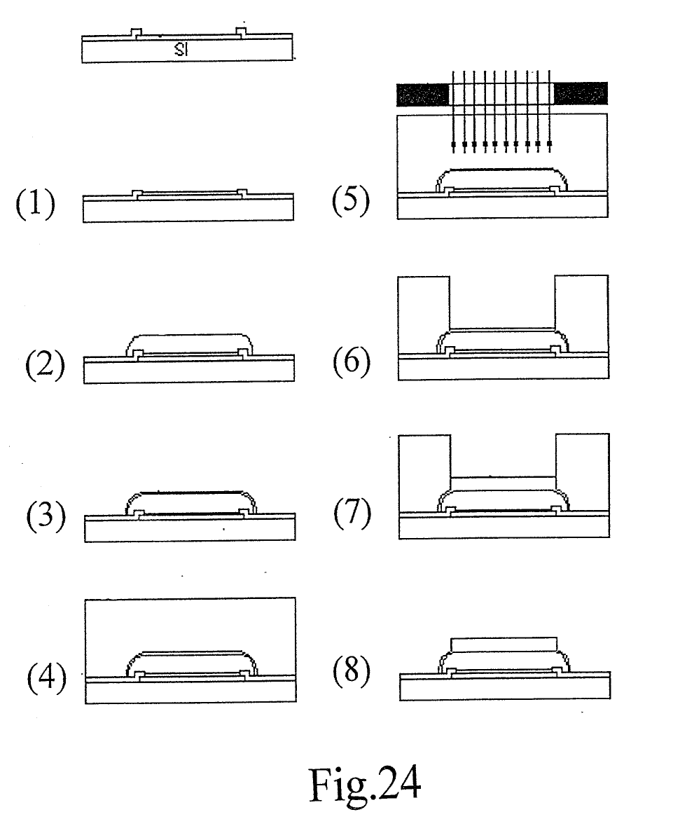

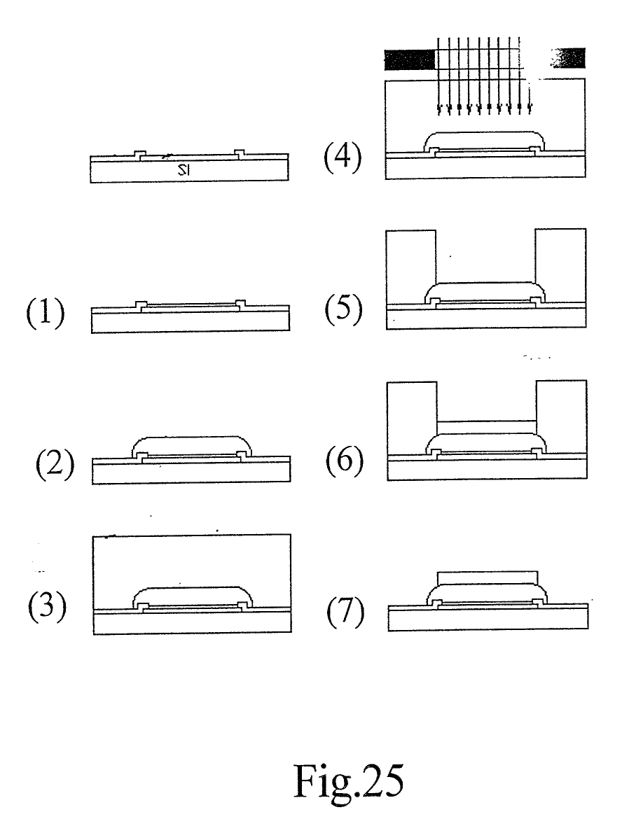

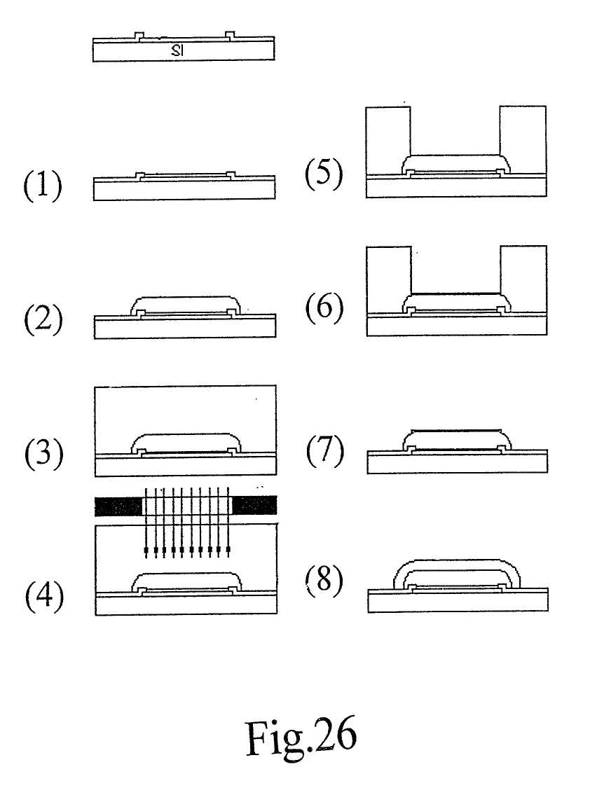

What is claimed is:

1. A metal bumping structure on the input/output connector of a substrate or wafer, which is a metal conductor composed of multiple metal layers overlap the connector pad, and it is characterized in that: the multiple metal layers which overlap to outer or upper metal layer is thinner than the inner or lower metal layer, and the outer or upper metal layer that form the pillar style whose conductivity, connectivity and corrosion resist are better than the inner or lower metal layer, such that the bumping connector has better conductivity, connectivity and not easy to be corroded.

2. The structure according to claim 1, wherein the multiple metal layers of the metal bumping structure is made of metal, its alloy or its compound.

3. The structure according to claim 1, wherein the metal bumping, structure is composed of double metal layer that overlap on connector pad, the inner or lower layer is Ni, its alloy or its compound, and the outer or upper layer is Au, its alloy or its compound.

4. The structure according to claim 3, wherein the deposition to the inner or lower metal layer, its alloy or its compound of the metal bumping, structure is repressed by the photoresist.

5. The structure according to claim 3, wherein the deposition to the outer or upper metal layer, its alloy or its compound of the metal bumping structure is repressed by the photoresist.

6. The structure according to claim 3, wherein the deposition to the inner or lower metal layer, its alloy or its compound of the metal bumping structure, and the deposition to the outer or upper metal layer, its alloy or its compound of the metal bumping structure are repressed by the photoresist.

7. The structure according to claim 1, wherein the metal bumping structure is composed of triple metal layer that overlap on connector pad, the inner or lower layer is Pd, its alloy or its compound, the middle layer is Ni, its alloy or its compound, and the outer or upper layer is Au, its alloy or its compound.

8. The structure according to claim 7, wherein the deposition to the inner or lower metal layer, its alloy or its compound and the middle metal layer of the metal bumping structure is repressed by the photoresist.

9. The structure according to claim 7, wherein the deposition to the outer or upper metal layer, its alloy or its compound and the middle metal layer of the metal bumping structure is repressed by the photoresist.

10. The structure according to claim 7, wherein the deposition to the inner or lower metal layer, its alloy or its compound and the middle metal layer of the metal bumping structure and the deposition to the outer or upper metal layer, its alloy or its compound and the middle metal layer of the metal bumping structure both are repressed by the photoresist.

11. The structure according to claim 1, wherein the outer metal layer of the multi-metal layer of the metal bumping structure is not extended to the rim of pillar, that is not to fully cover the inner or lower metal layer.

12. The structure according to claim 1, wherein the outer metal layer of the multi-metal layer of the metal bumping structure extends to the rim of pillar, that is fully cover the inner or lower metal layer such that not to be corroded.

13. The structure according to claim 1, wherein the metal bumping structure is constructed upon the input/output connector pad, and the bumping edge does not exceed the pad area.

14. The structure according to claim 1, wherein the metal bumping structure is constructed upon the input/output connector pad, and the bumping edge exceeds the pad area but does not exceed the one-second pitch between two pads.

15. The structure according to claim 1, wherein the metal bumping structure of the input/output connector pad conductor is composed of Al, Cu, Ag, Au, their alloies or their compounds, in order to construct and make use of the same or different metals, such that the well connectivity is obtained.

16. A method for manufacturing metal bumping structure on the input/output connector of a substrate or wafer, comprising the steps of electroless plating accompanies photoresist, exposure, developing and photoresist removing to construct a metal conductor of the multiple metal layers upon the input/output connector pad.

17. A method according to claim 16, in the step of electroless plating, which the metal ion is replaced in the silvent or, performing chemical reduction method in the solvent contains reducing agent, single or repeat mixing both of the former processes to attain, and adjust it depend on the elements or the concentration of the solvent to deposit a metal, its alloy or its compound, such that to construct the overlap of the multiple metal layers, and the outer or upper metal layer is thinner than the inner or lower metal layer, then the flatness of the top bumping connector without extension of the metal bumping is formed.

18. The method for manufacturing a metal bumping structure on the input/output connector of a substrate or according to claim 16, it comprises the steps of:
(1) Coating photoresist;
(2) Adding mask to exposure;
(3) Developing to expose the metal of the pad;
(4) Pre-treatment of the electroless plating;
(5) Plating a metal layer by electroless plating method;
(6) Photoresist removing;
(7) By electroless plating method, plating an another metal onto the surface of the metal layer to construct the bumping

19. The method for manufacturing a metal bumping structure on the input/output connector of a substrate or according to claim 18 wherein, when the original metal of the pad is Al, the manufacturing steps (4) (5) (7) are separately modified to:
(4) The Al on the pad is replaced by Zn, its alloy or its compound;
(5) In the step (4), the surface of Zn is replaced by Ni, its alloy or its compound;
(7) In the step (5), the upper edge and the rim surface of the Ni is replaced or deposited by Au, its alloy or its compound;
so as to construct the bumping.

20. The method for manufacturing a metal bumping structure on the input/output connector of a substrate or according to claim 18 wherein, when the original metal of the pad is Cu, the manufacturing steps (4) (5) (7) separately modify to:
(4) The Cu on the pad surface is replaced by Pd, alloy or compound;
(5) In the step (4), the surface of the Pd is replaced by Ni, its alloy or its compound;
(8) In the step (5), the upper edge and the rim surface of the Ni is replaced or deposited by Au, its alloy or its compound
so as to construct the bumping.

21. The method for manufacturing a metal bumping structure on the input/output connector of a substrate or according to claim 17, it comprises the steps of:
(1) Coating photoresist;
(2) Adding mask to exposure;
(3) Developing to expose the metal of the pad;
(4) Pre-treatment of the electroless plating;
(5) Plating one metal layer by electroless plating method;
(6) By electroless plating method, plating an another metal on the surface of the metal layer formed by step (5) to construct the bumping;
(7) Photoresist removing;
(8) By electroless plating method, again plating the same metal in the step (6) on the rim of the metal formed by step (5)
so as to construct the bumping.

22. The method for manufacturing a metal bumping structure on the input/output connector of a substrate or according to claim 21 wherein, when the original metal of the pad is Al, the manufacturing steps (4) (5) (6) (8) are separately modified to:
(4) The Al on the pad is replaced by Zn, alloy or compound;
(5) In the step (4), the surface of Zn is replaced by Ni, its alloy or its compound;
(6) In the step (5), the upper edge surface of Ni is replaced or deposited by Au, its alloy or its compound;
(8) In the step (5), the rim surface of Ni is replaced or deposited by Au, its alloy or its compound;
so as to construct the bumping.

23. The method for manufacturing a metal bumping structure on the input/output connector of a substrate or according to claim 21 wherein, when the original metal of the pad is Cu, the manufacturing steps (4) (5) (6) (8) are separately modified to:
(4) The Cu on the pad is replaced by Pd, its alloy or its compound;
(5) In the step (4), the surface of Pd is replaced by Ni, its alloy or its compound;
(6) In the step (5), the upper edge surface of Ni is replaced or deposited by Au, its alloy or its compound;
(8) In the step (5), the rim surface of Ni is replaced or deposited by Au, its alloy or its compound;
so as to construct the bumping.

24. The method for manufacturing a metal bumping structure on the input/output connector of a substrate or according to claim 16, it comprises the steps of:
(1) Coating photoresist;
(2) Adding mask to exposure;
(3) Developing to expose the metal of the pad;
(4) Pre-treatment of the electroless plating;
(5) Plating one metal layer by electroless plating method;
(6) By electroless plating method, plating an another metal on the surface of the metal layer formed by step (5);
(7) Photoresist removing;
so as to construct the bumping.

25. The method for manufacturing a metal bumping structure on the input/output connector of a substrate or according to claim 24 wherein, when the original metal of the pad is Al, the manufacturing steps (4) (5) (6) are separately modified to:
(4) The Al on the pad is replaced by Zn, its alloy or its compound;
(5) In the process number four, the surface of the Zn is replaced by Ni, alloy or compound;
(6) In the step (5), the upper edge and the rim surface of Ni is replaced or deposited by Au, its alloy or its compound;
so as to construct the bumping.

26. The method for manufacturing a metal bumping structure on the input/output connector of a substrate or according to claim 24 wherein, when the original metal of the pad is Cu, the manufacturing steps (4) (5) (6) are separately modified to:
(4) The Cu on the pad surface is replaced by Pd, its alloy or its compound;
(5) In the step (4), the surface of Pd is replaced by Ni, its alloy or its compound;
(6) In the step (5), the upper edge and the rim surface of Ni is replaced or deposited by Au, its alloy or its compound;
so as to construct the bumping.

27. The method for manufacturing a metal bumping structure on the input/output connector of a substrate or according to claim 16, it comprises the steps of:
(1) Pre-treatment of the electroless plating;
(2) Plating one metal layer by electroless plating method;
(3) By electroless plating method, plating an another metal on the surface of the metal layer formed by process number two;
(4) Coating photoresist;
(5) Adding mask to exposure;
(6) Developing to expose the top metal of the pad;
(7) By electroless plating method, plating the same thicker metal on the top surface of the metal layer formed by step (2);
(8) Photoresist removing;
So as to construct the bumping.

28. The method for manufacturing a metal bumping structure on the input/output connector of a substrate or according to claim 27 wherein, when the original metal of the pad is Al, the manufacturing steps (1) (2) (3) (7) are separately modified to:
(1) The Al on the pad is replaced by Zn, its alloy or its compound;
(2) In the step (1), the surface of Zn is replaced by Ni, its alloy or its compound;
(3) In the step (2), the surface of Ni is replaced or deposited by Au, its alloy or its compound;
(7) In the step (3), the top surface of the Au is deposited thicker by Au, its alloy or its compound;
so as too construct the bumping.

29. The method for manufacturing a metal bumping structure on the input/output connector of a substrate or according to claim 27 wherein, when the original metal of the pad is Cu, the manufacturing steps (1) (2) (3) (7) are separately modified to:
(1) The Cu on the pad surface is replaced by Pd, its alloy or its compound;
(2) In the step (1), the surface of Pd is replaced by Ni, its alloy or its compound;
(3) In the step (2), the surface of Ni is replaced or deposited by Au, its alloy or its compound;
(7) In the step (3), the top surface of the Au is deposited by a thicker layer of Au, its alloy or its compound;
so as to construct the bumping.

30. The method for manufacturing a metal bumping structure on the input/output connector of a substrate or according to claim 16, it comprises the steps of:
(1) Pre-treatment of the electroless plating;
(2) Plating one metal layer by electroless plating method;
(3) Coating photoresist;
(4) Adding mask to exposure;
(5) Developing to expose the top metal of the pad;
(6) By electroless plating method, plating an another metal on the surface of the metal layer formed by step (2);
(7) Photoresist removing;
so as to construct the bumping.

31. The method for manufacturing a metal bumping structure on the input/output connector of a substrate or according to claim 16 wherein, when the original metal of the pad is Al, the manufacturing steps (1) (2) (3) are separately modified to:
(1) Pre-treatment of the electroless plating;
(2) Plating one metal layer by electroless plating method;
(3) Coating photoresist;
(4) Adding mask to exposure;
(5) Developing to expose the top metal of the pad;
(6) By electroless plating method, plating an another metal on the surface of the metal layer formed by step (2);
(7) Photoresist removing;
so as to construct the bumping.

32. The method for manufacturing a metal bumping structure on the input/output connector of a substrate or according to claim 30 wherein, when the original metal of the pad is Cu, the manufacturing steps (1) (2) (3) are separately modified to:
(1) The Cu of the pad surface is replaced by Pd, its alloy or its compound;
(2) In the step (1), the surface of the Pd is replaced by Ni, its alloy or its compound;
(3) In the step (2),. the surface of the Ni is replaced or deposited by Au, its alloy or its compound;
so as to construct the bumping.

33. The method for manufacturing a metal bumping structure on the input/output connector of a substrate or according to claim 16, it comprises the steps of:
(1) Pre-treatment of the electroless plating;
(2) Plating one metal layer by electroless plating method;
(3) Coating photoresist;
(4) Adding mask to exposure;
(5) Developing to expose the top metal of the pad;
(6) By electroless plating method, plating an another metal on the surface of the metal layer formed by step (2);
(7) Photoresist removing;
(8) By electroless plating method, plating a thicker layer of metal same as that used in step (6) on the rim of the metal formed by step (2) and on the top surface of the metal layer formed by step (6);
so as to construct the bumping.

34. The method for manufacturing a metal bumping structure on the input/output connector of a substrate or according to claim 33 wherein, when the original metal of the pad is Al, the manufacturing steps (1) (2) (3) (8) are separately modified to:
(1) The Al on the pad surface is replaced by Zn, its alloy or its compound;
(2) In the step (1), the surface of Zn is replaced by Ni, its alloy or its compound;
(3) In the step (2), the surface of Ni is replaced or deposited by Au, its alloy or its compound;
(8) The rim in the step (2) and the top surface in the step (6) are plating thicker layers of metal same as that used in step (6);
so as to construct the bumping.

35. The method for manufacturing a metal bumping structure on the input/output connector of a substrate or according to claim 33 wherein, when the original metal of the pad is Cu, the manufacturing steps (1) (2) (3) (8) are separately modified to:
(1) The Cu of the pad surface is replaced by Pd, its alloy or its compound;
(2) In the step (1), the surface of the Pd is replaced by Ni, its alloy or its compound;
(3) In the step (2), the surface of Ni is replaced or deposited by Au, its alloy or its compound;
(8) The rim in the step (2) and the top surface in the step (6) are plating thicker layers of metal same as that used in step (6);
so as to construct the bumping.
